(19) United States
(12) Patent Application Publication
(10) Pub. No.: US 2015/0029664 A1
(43) Pub. Date: Jan. 29, 2015

(54) FAN ANTI-CORROSION STRUCTURE

(71) Applicant: ASIA VITAL COMPONENTS CO., LTD., New Taipei City (TW)

(72) Inventors: Wei-Cheng Chen, New Taipei City (TW); Ping-Chi Kuo, New Taipei City (TW); Hsu-Jung Lin, New Taipei City (TW)

(73) Assignee: ASIA VITAL COMPONENTS CO., LTD., New Taipei City (TW)

(21) Appl. No.: 13/949,190

(22) Filed: Jul. 23, 2013

(51) Int. Cl. H05K 7/20

(52) U.S. Cl. CPC H05K 7/20172
USPC 361/695

(57) ABSTRACT

A fan anti-corrosion structure includes a base seat, a circuit board and at least one coating unit. The base seat has a sidewall and a bearing cup. A rest face extends from the sidewall toward the bearing cup. The circuit board is fitted around the bearing cup and disposed on the rest face. A closed space is defined between the circuit board and the base seat. The coating is coated on the circuit board. The circuit board is protected from the corrosion of the moisture and the salt fog by the coating unit and the closed space. Also, the cost of the mold for forming the coating unit is saved to lower the manufacturing cost.

### BACKGROUND OF THE INVENTION

1. Field of the Invention

The present invention relates generally to a fan anti-corrosion structure, which is able to protect the circuit board from the corrosion of the moisture and the salt fog. The fan anti-corrosion structure is formed without using any mold. Therefore, the cost of the mold is saved to lower the manufacturing cost.

2. Description of the Related Art

A conventional cooling fan generally includes a fan frame body, a bearing cup seat, a fan impeller, a circuit board and a stator assembly.

The cooling fan has been more and more widely applied to various fields including CPU of an electronic apparatus, server, power supply, communication chassis, communication base station, etc. In some cases, the cooling fan is used in a severe environment such as a moist environment or a salt fog environment. In the case that the cooling fan is not provided with a waterproof and anti-corrosion structure, the moisture and salt fog will infiltrate into the stator assembly and the bearing or even the circuit board to corrode these components. As a result, the lifetime of the cooling fan will be shortened.

A sealant filling technique has been disclosed to solve the above problem. Referring to FIG. 1, in the sealant filling technique, the stator assembly 11, the bearing cup 13 and the circuit board 12 are first placed into a sealant filling mold. Then an anti-corrosion material 14 is filled into the mold to enclose the circuit board 12. After the anti-corrosion material 14 is solidified and shaped, the circuit board 12 is taken out from the mold. The anti-corrosion material 14 serves to protect the electronic components from corrosion of the moisture and the salt fog and thus avoid short-circuit and burnout of the cooling fan.

However, due to the cost of the mold, the total manufacturing cost of the cooling fan is increased. Moreover, after repeatedly used several times, the mold must be replaced with a new one. This also leads to increase of the total manufacturing cost. In addition, the electronic components of the circuit board 12 are enclosed by the anti-corrosion material 14. As a result, the heat dissipation effect of the circuit board 12 is deteriorated. This will lead to rise of temperature of the circuit board.

According to the above, the conventional fan anti-corrosion structure has the following shortcomings:
1. The fan anti-corrosion structure is formed by means of a mold so that the manufacturing cost is increased.
2. The mold must be frequently replaced so that the manufacturing cost is increased.
3. The heat dissipation effect is deteriorated.

### SUMMARY OF THE INVENTION

It is therefore a primary object of the present invention to provide a fan anti-corrosion structure, which is able to protect the circuit board from the corrosion of the moisture and the salt fog. The fan anti-corrosion structure is formed without using any mold. Therefore, the cost of the mold is saved to lower the manufacturing cost

It is a further object of the present invention to provide the above fan anti-corrosion structure, which can enhance the heat dissipation efficiency of the fan.

To achieve the above and other objects, the fan anti-corrosion structure of the present invention includes a base seat, a circuit board, a stator assembly and at least one coating unit.

The base seat has a sidewall and a bearing cup extending from the base seat. At least one rest face extending from the sidewall toward the bearing cup. The circuit board is fitted around the bearing cup and disposed on the rest face. At least one electronic component is disposed on one face of the circuit board, which face is proximal to the base seat. The electronic component is disposed in the closed space. The stator assembly includes multiple silicon steel sheets. The stator assembly is fitted around the bearing cup and disposed on the circuit board. The coating unit is coated on the other face of the circuit board, which face is distal from the base seat. At least one electronic component is disposed on the other face of the circuit board, which face is distal from the base seat. The coating unit is also coated on the electronic component. The circuit board is protected from the corrosion of the moisture and the salt fog by the coating unit and the closed space. Also, the fan anti-corrosion structure is formed without using any mold so that the cost of the mold for forming the coating unit is saved to lower the manufacturing cost.

According to the above, the present invention has the following advantages:
1. The fan anti-corrosion structure is formed without using any mold so that the cost of the mold for forming the coating unit is saved.
2. The manufacturing cost is lowered.
3. The heat dissipation efficiency of the fan is enhanced.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a sectional view of a conventional fan anti-corrosion structure;

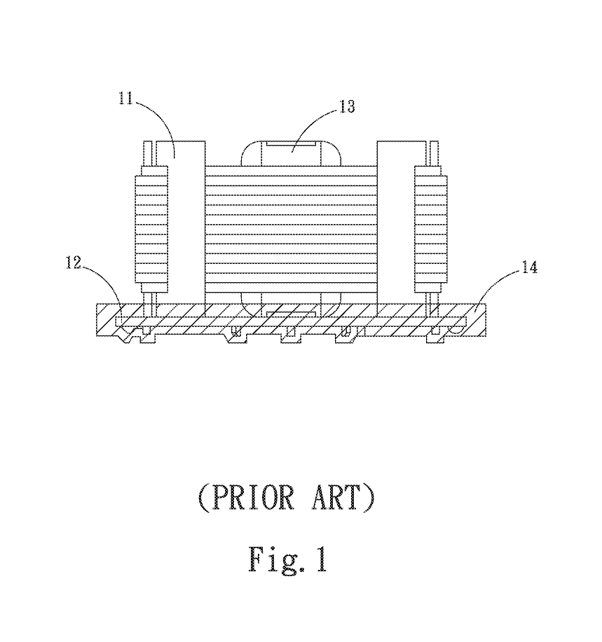

FIG. 2 is a sectional view of a preferred embodiment of the present invention; and

FIG. 3 is an enlarged view of circled area of FIG. 2.

### DETAILED DESCRIPTION OF THE PREFERRED EMBODIMENTS

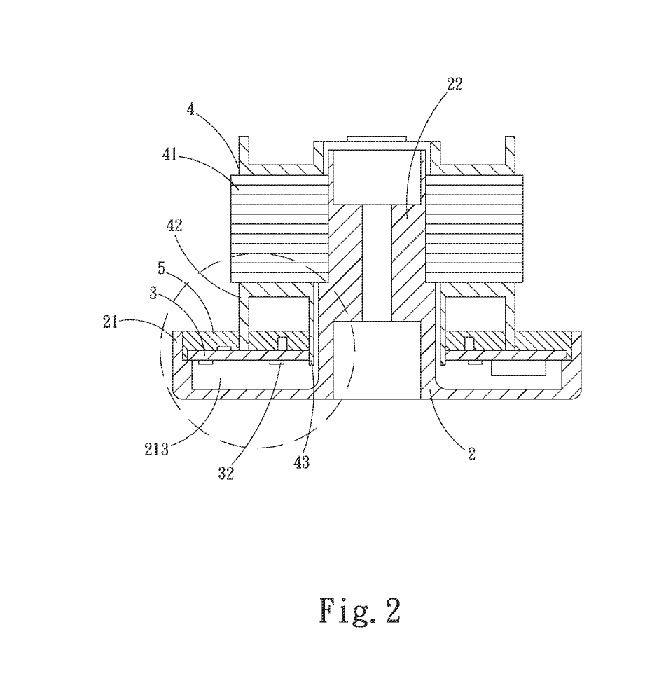

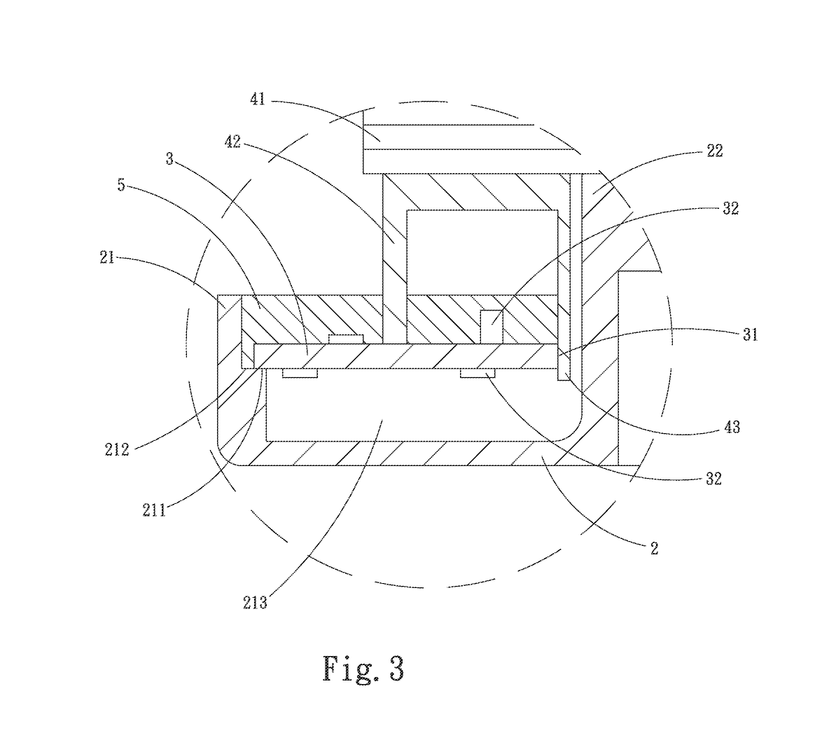

Please refer to FIGS. 2 and 3. FIG. 2 is a sectional view of a preferred embodiment of the present invention. FIG. 3 is an enlarged view of circled area of FIG. 2. According to the preferred embodiment, the fan anti-corrosion structure of the present invention includes a base seat 2, a circuit board 3, a stator assembly 4 and a coating unit 5. The base seat 2 has an annular sidewall 21. A bearing cup 22 upward extends from a center of the base seat 2. At least one rest face 211 extends from the sidewall 21 toward the bearing cup 22. In this embodiment, the rest face 211 is, but not limited to, annularly formed on an inner circumference of the sidewall 21.

The circuit board 3 is formed with a central hole 31. Via the central hole 31, the circuit board 3 is fitted around the bearing cup 22 and disposed on the rest face 211. The circuit board 3 has a configuration corresponding to the rest face 211. When the circuit board 3 is disposed on the rest face 211, a closed space 213 is defined between one face of the circuit board 3 and the base seat 2. In addition, at least one passage 212 is defined between the circuit board 3 and the sidewall 21 of the base seat 2. At least one electronic component 32 is disposed on one face of the circuit board 3, which face is proximal to the base seat 2. The electronic component 32 is disposed in the closed space 213. At least one electronic component 32 is disposed on the other face of the circuit board 3, which face is distal from the base seat 2.

The stator assembly 4 includes multiple silicon steel sheets 41, a first support 42 and a second support 43. The stator assembly 4 is fitted around the bearing cup 22. The first support 42 is disposed on the circuit board 3. The second support 43 extends to the base seat 2 into contact with the circumference of the central hole 31 of the circuit board 3 to define the closed space 213.

The coating unit 5 is coated on the other face of the circuit board 3, which face is distal from the base seat 2, and coated on the electronic component 32. The coating unit 5 is also disposed in the passage 212 and coated on an end of the first support 42, which end is disposed on the circuit board 3. Two sides of the coating unit 5 are restricted between the sidewall 21 and the second support 43. In this embodiment, the coating unit 5 is made of anti-corrosion material. In the case that the fan is used in an environment such as a salt fog environment that will corrode the circuit board 3, the circuit board 3 and the electronic components 32 disposed on two faces of the circuit board 3 are respectively protected from the corrosive environment by the closed space 213 and the coating unit 5. Alternatively, the coating unit 5 can be directly coated on the circuit board 3 and restricted between the sidewall 21 and the second support 43. In this case, the cost of the mold for forming the coating unit 5 can be saved. According to the above arrangement, the circuit board 3 is protected from the corrosion of the moisture and the salt fog by the coating unit 5 and the closed space 213. Also, the cost of the mold for forming the coating unit 5 can be saved to lower the manufacturing cost.

The present invention has been described with the above embodiments thereof and it is understood that many changes and modifications in the above embodiments can be carried out without departing from the scope and the spirit of the invention that is intended to be limited only by the appended claims.

What is claimed is:

1. A fan anti-corrosion structure comprising:
a base seat having a sidewall, a bearing cup extending from the base seat, at least one rest face extending from the sidewall toward the bearing cup;
a circuit board fitted around the bearing cup and disposed on the rest face, a closed space being defined between one face of the circuit board and the base seat;
a stator assembly including multiple silicon steel sheets, the stator assembly being fitted around the bearing cup and disposed on the circuit board; and
at least one coating unit coated on the other face of the circuit board, which face is distal from the base seat.

2. The fan anti-corrosion structure as claimed in claim 1, wherein at least one passage is defined between a periphery of the circuit board and the sidewall of the base seat.

3. The fan anti-corrosion structure as claimed in claim 1, wherein the circuit board is formed with a central hole, the circuit board being fitted around the bearing cup via the central hole.

4. The fan anti-corrosion structure as claimed in claim 2, wherein the coating unit is disposed in the passage.

5. The fan anti-corrosion structure as claimed in claim 1, wherein the stator assembly further includes a first support, the first support being disposed on the circuit board, the coating unit being coated on an end of the first support, which end is disposed on the circuit board.

6. The fan anti-corrosion structure as claimed in claim 3, wherein the stator assembly further includes a second support in adjacency to the bearing cup, one end of the second support extending to the base seat into contact with a circumference of the central hole of the circuit board to define the closed space.

7. The fan anti-corrosion structure as claimed in claim 1, wherein at least one electronic component is disposed on one face of the circuit board, which face is proximal to the base seat, the electronic component being disposed in the closed space.

8. The fan anti-corrosion structure as claimed in claim 1, wherein at least one electronic component is disposed on the other face of the circuit board, which face is distal from the base seat, the coating unit being coated on the electronic component.

9. The fan anti-corrosion structure as claimed in claim 1, wherein the coating unit is made of anti-corrosion material.
